(19) United States
(12) Patent Application Publication
(10) Pub. No.: US 2026/0304749 A1
(43) Pub. Date: Oct. 1, 2026

(54) SEMICONDUCTOR DEVICE AND METHOD FOR MANUFACTURING THE SAME

(71) Applicant: SK hynix Inc., Gyeonggi-do (KR)

(72) Inventors: Se Ra HWANG, Gyeonggi-do (KR); Seung Wan CHU, Gyeonggi-do (KR)

(21) Appl. No.: 19/578,892

(22) Filed: Mar. 26, 2026

(30) Foreign Application Priority Data
Mar. 27, 2025 (KR) 10-2025-0039732

(51) Int. Cl. H10B 12/00; H10D 30/67

(52) U.S. Cl. CPC H10B 12/315; H10B 12/0335; H10B 12/482; H10B 12/488; H10D 30/6728; H10D 30/6735

(57) ABSTRACT

A semiconductor device including a vertical active region is disclosed. The semiconductor device includes an active region, one side of which is in contact with a bitline; a storage node contact configured to contact the other side of the active region; and an insulation pattern disposed between the storage node contact and another storage node contact adjacent to the storage node contact. The insulation pattern includes a first insulation pattern layer including silicon oxide; and a second insulation pattern layer including silicon nitride.

### CROSS-REFERENCE TO RELATED APPLICATION

This patent application claims the priority and benefits of Korean patent application No. 10-2025-0039732, filed on Mar. 27, 2025, the disclosure of which is incorporated herein by reference in its entirety.

### TECHNICAL FIELD

The embodiments of the present disclosure generally relate to a semiconductor device, and more particularly to a semiconductor device including a vertical active region.

### BACKGROUND

As miniaturization and higher degrees of integration of semiconductor devices have become major issues, memory cells included in semiconductor devices may be formed to have three-dimensional (3D) patterns. Miniaturized memory cells with three-dimensional (3D) patterns may be equipped with configurations that improve operation characteristics of the memory cells.

### SUMMARY

Various embodiments of the present disclosure relate to an insulation pattern for preventing contact between an active region and a silicon nitride layer.

In accordance with an embodiment of the present disclosure, a semiconductor device may include an active region, one side of which is in contact with a bitline; a storage node contact configured to contact the other side of the active region; and an insulation pattern disposed between the storage node contact and another storage node contact adjacent to the storage node contact, wherein the insulation pattern includes a first insulation pattern layer including silicon oxide; and a second insulation pattern layer including silicon nitride.

In some embodiments, the semiconductor device may further include a wordline configured to extend along a sidewall of the active region; and a back gate configured to extend parallel to the wordline.

In some embodiments, the bitline may extend in a first direction, the wordline may extend in a second direction, and the active region may extend in a third direction orthogonal to the first and second directions.

In some embodiments, the active region may be in contact with the first insulation pattern layer.

In some embodiments, the active region may include silicon.

In some embodiments, the storage node contact may include polysilicon.

In some embodiments, the first insulation pattern layer may be formed through an oxidation process.

In some embodiments, the first insulation pattern layer may be formed through a deposition process.

In some embodiments, the first insulation pattern layer may be formed at a temperature of 900° C or less.

In accordance with another embodiment of the present disclosure, a method for manufacturing a semiconductor device may include forming a pre-storage node contact layer over an active region; etching at least a portion of the pre-storage node contact layer; forming a first pre-insulation pattern layer over a region where the pre-storage node contact layer is etched; forming a second pre-insulation pattern layer over the first pre-insulation pattern layer; and forming an insulation pattern layer by etching at least a portion of each of the first pre-insulation pattern layer and the second pre-insulation pattern layer.

In some embodiments, the active region may include silicon.

In some embodiments, the pre-storage node contact layer may include polysilicon.

In some embodiments, the first pre-insulation pattern layer may be formed through an oxidation process.

In some embodiments, the first pre-insulation pattern layer may be formed through a deposition process.

In some embodiments, the first pre-insulation pattern layer may be formed at a temperature of 900° C or less.

It is to be understood that both the foregoing general description and the following detailed description of the present disclosure are illustrative and descriptive and are intended to provide further description of the embodiments of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a cross-sectional view illustrating a semiconductor device according to an embodiment of the present disclosure.

FIGS. 2-7 are cross-sectional views illustrating a method for manufacturing the semiconductor device according to an embodiment of the present disclosure.

### DETAILED DESCRIPTION

The embodiments of the present disclosure provide a semiconductor device including a vertical active region that may be used in configurations to substantially address one or more technical or engineering issues and to mitigate limitations or disadvantages encountered in some other semiconductor devices. Some embodiments of the present disclosure relate to an insulation pattern for preventing contact between an active region and a silicon nitride layer. In recognition of the issues above, the present disclosure provides a semiconductor device that enables the insulation pattern disposed between storage node contacts to include a plurality of insulation pattern layers, so that contact between the active region and the silicon nitride layer due to damage caused in the manufacturing process can be prevented.

Reference will now be made in detail to the embodiments of the present disclosure which are illustrated in the accompanying drawings. Wherever possible, the same reference numbers will be used throughout the drawings to refer to the same or like parts. While the embodiments are susceptible to various modifications and alternative forms, specific embodiments thereof are shown in the drawings. However, the embodiments should not be construed as being limited to the embodiments set forth herein.

Hereinafter, various embodiments will be described with reference to the accompanying drawings. However, it should be understood that the embodiments are not limited to specific embodiments, but includes various modifications, equivalents and/or alternatives of the embodiments. The embodiments of the present disclosure may provide a variety of advantageous effects capable of being directly or indirectly recognized by one of ordinary skill in the art.

In the following description, a detailed description of related known configurations or functions incorporated herein will be omitted to avoid obscuring the subject matter.

The terminology used herein is for the purpose of describing particular embodiments only and is not intended to be limiting of the scope of the present disclosure. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

Hereinafter, a semiconductor device and a method for manufacturing the same according to embodiments of the present disclosure will be described in detail with reference to the attached drawings.

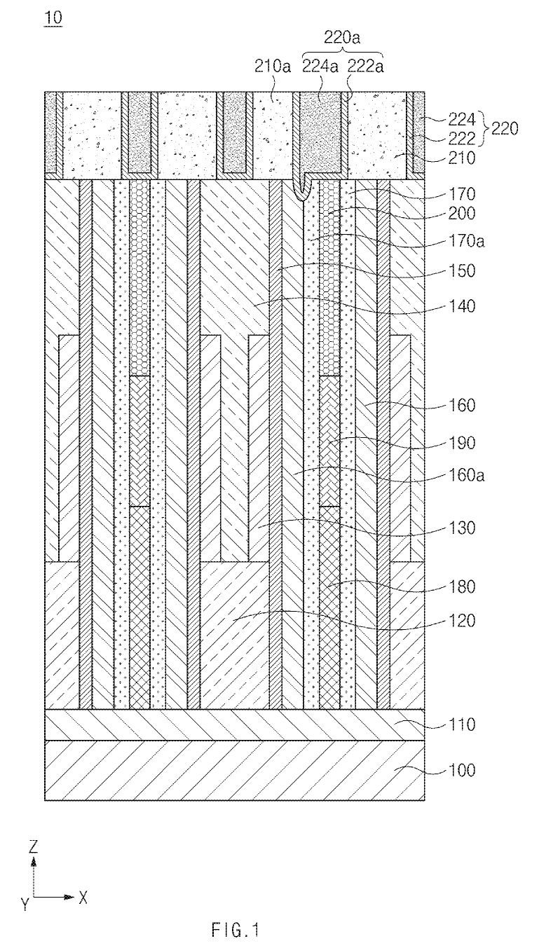

FIG. 1 is a cross-sectional view illustrating a semiconductor device 10 according to an embodiment of the present disclosure.

Referring to FIG. 1, the semiconductor device 10 may include a bitline lower layer 100 and a bitline 110 disposed over the bitline lower layer 100. The bitline lower layer 100 may include a substrate and an insulating material layer. The substrate may include a semiconductor substrate such as a silicon substrate, a germanium substrate, or a silicon-germanium substrate.

The bitline 110 may include a conductive material. The conductive material may be, for example, any of a doped semiconductor material, a conductive metal nitride, a metal, or a metal-semiconductor compound. The bitline 110 may have a line shape extending in a first direction (X-axis direction).

A wordline lower sealing layer 120 may be an insulating layer disposed over the bitline 110. The wordline lower sealing layer 120 may include, for example, silicon nitride.

The wordline lower sealing layer 120 may be disposed between the wordline 130 and the bitline 110. The wordline lower sealing layer 120 may serve as a layer that electrically isolates the wordline 130 from the bitline 110.

The wordline 130 may be a conductive material layer disposed over the wordline lower sealing layer 120. The wordline 130 may include a conductive material. The conductive material may be, for example, any of a doped semiconductor material, a conductive metal nitride, a metal, or a metal-semiconductor compound. The wordline 130 may have a shape extending in a second direction (Y-axis direction).

A wordline upper sealing layer 140 may be an insulating layer that is disposed between adjacent wordlines 130 and also overlaps with the wordlines 130. The wordline upper sealing layer 140 may include, for example, silicon oxide.

A wordline isolation layer 150 may be disposed between the wordline 130 and the active region 160, and may serve to electrically isolate the wordline 130 from the active region 160. The wordline isolation layer 150 may function as a gate insulating layer, and may include, for example, silicon oxide.

The active region 160 may be a region in which a channel is formed during the operation of the semiconductor device 10, and may include a semiconductor material.

The semiconductor material may include, for example, doped polysilicon, undoped polysilicon, amorphous silicon, amorphous indium gallium zinc oxide (IGZO), indium zinc oxide (IZO), indium tin oxide (ITO), and indium oxide (InO₃).

The active region 160 may have a shape in which one side contacts the bitline 110 and extends in a direction orthogonal to the bitline 110. The active region 160 may have a shape extending in a third direction (Z-axis direction).

A back gate isolation layer 170 may be disposed between the active region 160 and the back gate 190, and may electrically isolate the active region 160 from the back gate 190. The back gate isolation layer 170 may include, for example, silicon oxide.

A back gate lower sealing layer 180 may be disposed between the back gate 190 and the bitline 110, and may include, for example, silicon oxide. The back gate lower sealing layer 180 may electrically isolate the back gate 190 from the bitline 110.

The back gate 190 may be disposed between adjacent active regions 160, and may be isolated from the active regions 160 by the back gate isolation layer 170. The back gate 190 may have a shape extending in the second direction (Y-axis direction).

The back gate 190 may serve to block interference between adjacent wordlines 130. To prevent interference between the wordlines 130, a voltage different from the voltage applied to the wordlines 130 may be provided to the back gate 190. For example, when an active-level voltage is applied to the wordlines 130, a ground voltage may be provided to the back gate 190.

A back gate upper sealing layer 200 may be an insulating layer that electrically isolates the back gate 190 from the insulation pattern 220 and the storage node contact 210. The back gate upper sealing layer 200 may include, for example, silicon nitride.

The storage node contact 210 may include a conductive material, and may be in contact with one side of the active region 160. The storage node contact 210 may be connected to a storage element (not shown) included in the semiconductor device.

The storage node contact 210 may include a metal, a metal mixture, a metal alloy, titanium nitride, tungsten, polysilicon, or a combination thereof. For example, the storage node contact 210 may include polysilicon.

The insulation pattern 220 may be disposed between adjacent storage node contacts 210, and may include an insulating material that electrically isolates the storage node contacts 210 from each other. The insulation pattern 220 may include a plurality of layers.

The insulation pattern 220 may include, for example, a first insulation pattern layer 222 and a second insulation pattern layer 224. In some embodiments, the first insulation pattern layer 222 may include, for example, silicon oxide, and the second insulation pattern layer 224 may include silicon nitride.

In some embodiments, a method for forming the storage node contact 210 may include allowing a pre-storage node contact layer including a conductive material to overlap with the wordline upper sealing layer 140, the wordline isolation layer 150, the active region 160, the back gate isolation layer 170, and the back gate upper sealing layer 200; and etching the remaining regions other than a region where the storage node contact 210 is to be formed.

The pre-storage node contact layer may be a polysilicon layer. The pre-storage node contact layer may be formed to be in contact with the active region 160.

During the process of etching a portion of the pre-storage node contact layer to define the storage node contact 210, a portion of the storage node contact 210 may be over-etched. In this case, the over-etched storage node contact may be referred to as a damaged storage node contact 210a. In some embodiments, “storage node contact” may be referred to as “first storage contact” and “damaged storage node contact” may be referred to as “second storage contact”.

A damaged active region 160a and a damaged back gate isolation layer 170a may be formed below the damaged storage node contact 210a caused by over-etching. In some embodiments, “active region” may be referred to as “first active region” and “damaged active region” may be referred to as “second active region”.

A damaged-portion insulation pattern 220a may be formed over the damaged active region 160a and the damaged back gate isolation layer 170a. The damaged-portion insulation pattern 220a may have a shape that gap-fills the over-etched region. The damaged-portion insulation pattern 220a may contact the damaged active region 160a. The insulation pattern 220 may be spaced apart from the active region 160 and the damaged active region 160a. In some embodiments, “insulation pattern” may be referred to as “first insulation pattern” and “damaged-portion insulation pattern” may be referred to as “second insulation pattern”.

The damaged-portion insulation pattern 220a may include a first damaged-portion insulation pattern layer 222a and a second damaged-portion insulation pattern layer 224a.

The first damaged-portion insulation pattern layer 222a may include, for example, silicon oxide. Since the first damaged-portion insulation pattern layer 222a includes silicon oxide, direct contact between the damaged active region 160a and the second damaged-portion insulation pattern layer 224a including silicon nitride can be prevented.

In some embodiments, contact between the damaged active region 160a including polysilicon and the second damaged-portion insulation pattern layer 224a including silicon nitride can be prevented, so that the concentration of interface traps formed in the damaged active region 160a can be reduced.

The interface traps are defects that occur at a contact surface between a silicon material and a silicon compound. As the concentration of interface traps increases, the electrical characteristics of the semiconductor device may deteriorate.

In the case of an interface between silicon (e.g., the active region 160) and silicon nitride (e.g., the first insulation pattern layer 222), the interface trap concentration may be higher than at an interface between silicon and silicon oxide.

Due to the electrical characteristics of silicon atoms, bonding between silicon and oxygen may be more stable than bonding between silicon and nitrogen. Accordingly, the concentration of dangling bonds at the silicon–silicon oxide interface may be lower than that at the silicon–silicon nitride interface.

In addition, nitride has a higher occurrence rate of fixed charges and mobile charges compared to silicon oxide, so that trap generation at the silicon–silicon nitride interface may be easier than at the silicon–silicon oxide interface.

The semiconductor device according to an embodiment of the present disclosure may reduce the concentration of interface traps that may occur in the damaged active region 160a by preventing direct contact between the damaged active region 160a and the silicon nitride layer, thereby improving the operational characteristics of the semiconductor device.

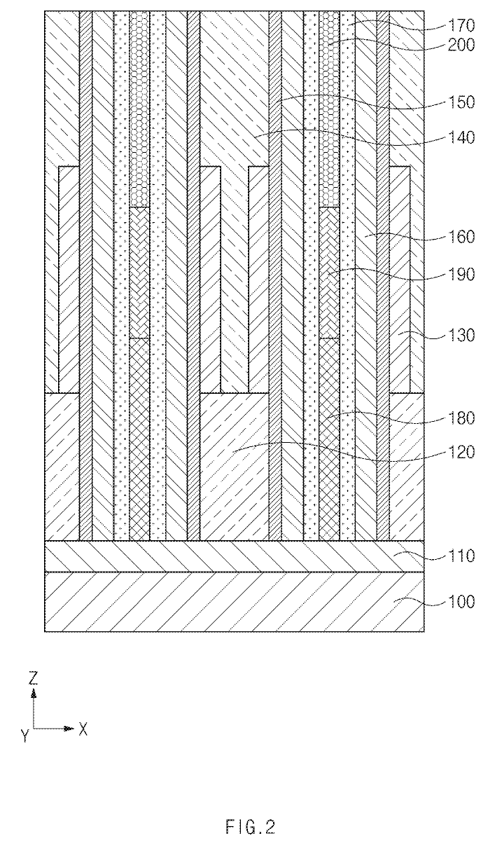

FIGS. 2-7 are cross-sectional views illustrating a method for manufacturing the semiconductor device according to an embodiment of the present disclosure.

In FIGS. 2-7, detailed descriptions of the configurations described with reference to FIG. 1 are omitted for brevity.

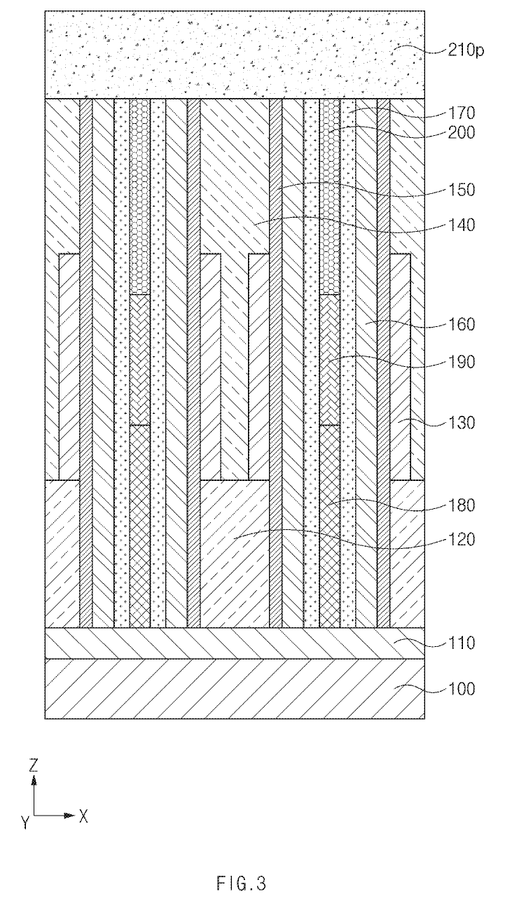

FIG. 2 is a cross-sectional view illustrating a portion of the semiconductor device prior to the formation of a pre-storage node contact layer 210p (see FIG. 3).

The semiconductor device may include a bitline lower layer 100 and a bitline 110. The wordline lower sealing layer 120 may be disposed over the bitline 110, and the wordline 130 may be disposed over the wordline lower sealing layer 120.

The wordline upper sealing layer 140 may be disposed between adjacent wordlines 130, and the wordline isolation layer 150 may be disposed between the wordline 130 and the active region 160.

The active region 160 may include silicon, and may be disposed between the back gate 190 and the wordline 130. The back gate isolation layer 170 may be disposed between the active region 160 and the back gate 190. The back gate lower sealing layer 180 may be disposed between the back gate 190 and the bitline 110.

The back gate upper sealing layer 200 may be an insulating layer region disposed over the back gate 190.

Referring to FIG. 3, a pre-storage node contact layer 210p may be formed to contact the wordline upper sealing layer 140, the wordline isolation layer 150, the active region 160, the back gate isolation layer 170, and the back gate upper sealing layer 200. The pre-storage node contact layer 210p may include, for example polysilicon. In some embodiments, the pre-storage node contact layer 210p may be formed through a deposition process.

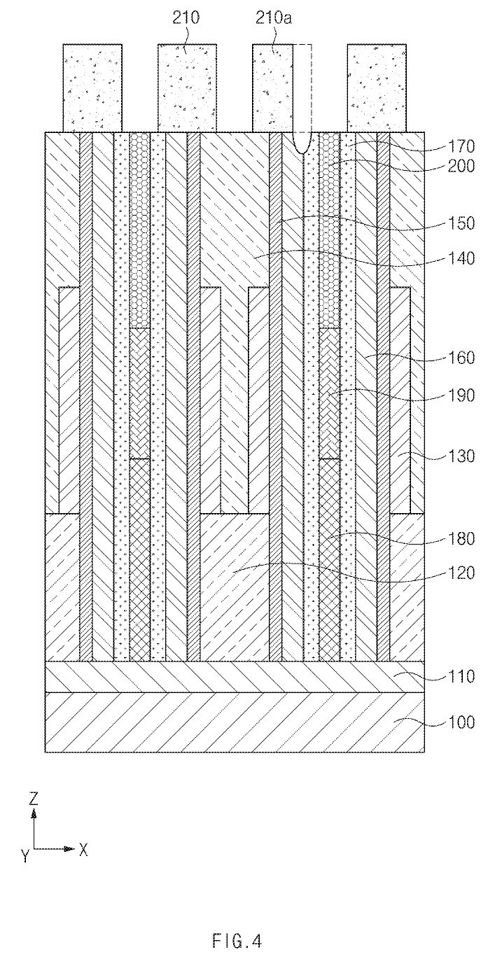

Referring to FIG. 4, a storage node contact 210 may be formed by etching at least a portion of the pre-storage node contact layer 210p (see FIG. 3). At this time, a portion of the pre-storage node contact layer 210p (see FIG. 3) may be over-etched, resulting in the formation of a damaged storage node contact 210a.

In addition, when the pre-storage node contact layer 210p (see FIG. 3) is over-etched, the back gate isolation layer 170 and the active region 160 that are disposed below the pre-storage node contact layer 210p (see FIG. 3) may also be over-etched. When the back gate isolation layer 170 and the active region 160 are over-etched, a damaged back gate isolation layer 170a and a damaged active region 160a may be formed.

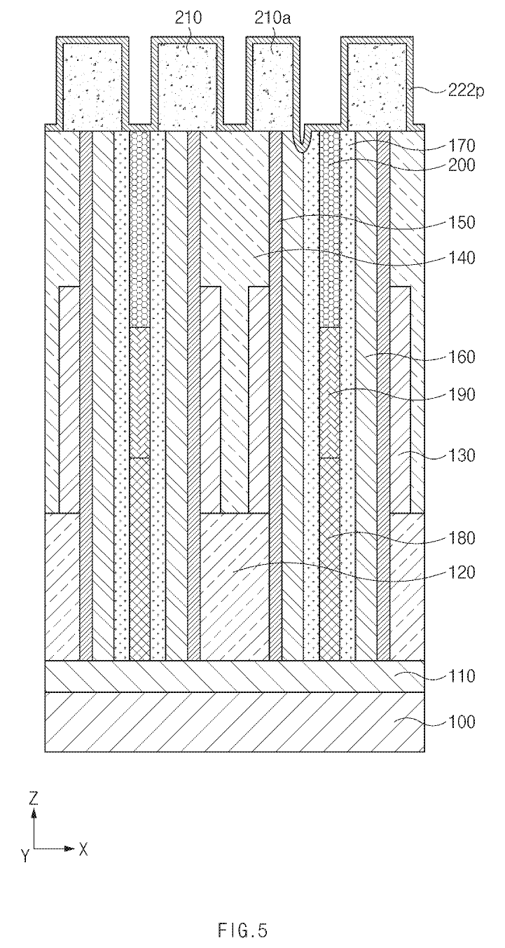

Referring to FIG. 5, a first pre-insulation pattern layer 222p may be formed over the storage node contact 210 and the damaged storage node contact 210a.

The first pre-insulation pattern layer 222p may include, for example, silicon oxide. In some embodiments, the first pre-insulation pattern layer 222p may be formed through an oxidation process. In another embodiment, the first pre-insulation pattern layer 222p may be formed through a deposition process. The deposition process may be, for example, one of a physical vapor deposition (PVD), a chemical vapor deposition (CVD), or an atomic layer deposition (ALD).

Using silicon oxide for the first pre-insulation pattern layer 222p is advantageous because the first pre-insulation pattern layer 222p adjusts the concentration of any interface traps generated at the interface between the damaged active region 160a and the first pre-insulation pattern layer 222p. More specifically, when the first pre-insulation pattern layer 222p includes silicon oxide, the interface trap concentration is reduced substantially compared to a case where the first pre-insulation pattern layer 222p includes silicon nitride.

The first pre-insulation pattern layer 222p may be formed between adjacent storage node contacts 210 or between the storage node contact 210 and the damaged storage node contact 210a.

The first pre-insulation pattern layer 222p may be formed at a temperature of 900° C or lower for preventing excessive diffusion of oxygen.

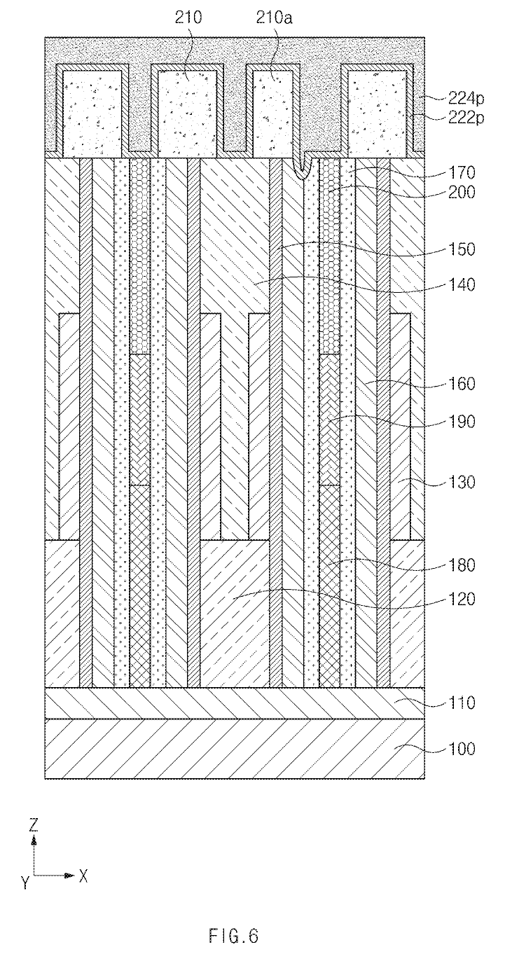

Referring to FIG. 6, a second pre-insulation pattern layer 224p may be formed over the first pre-insulation pattern layer 222p.

The second pre-insulation pattern layer 224p may include silicon nitride. In some embodiments, the second pre-insulation pattern layer 224p may be formed through a deposition process.

The second pre-insulation pattern layer 224p may overlap with the entire upper surface of the first pre-insulation pattern layer 222p.

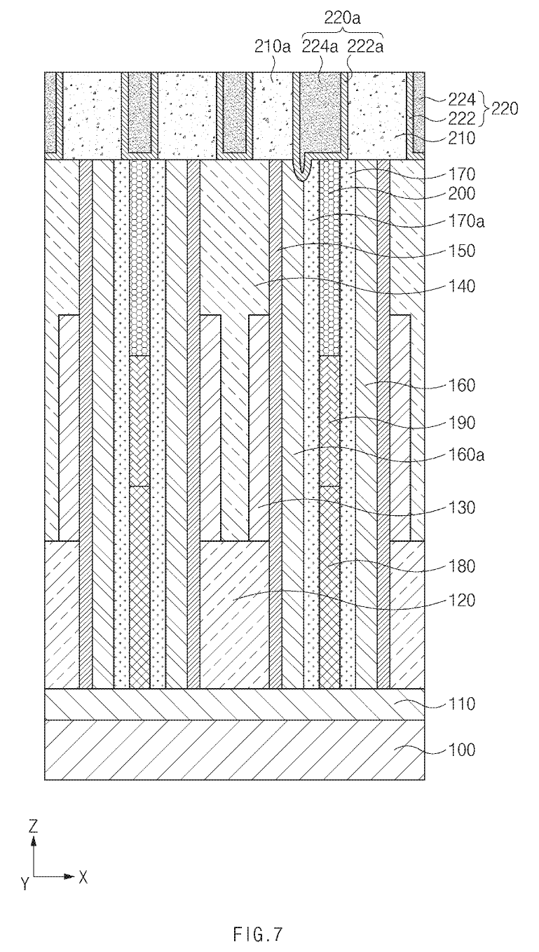

Referring to FIG. 7, an insulation pattern 220 and a damaged-portion insulation pattern 220a may be formed by etching at least portions of the first pre-insulation pattern layer 222p and the second pre-insulation pattern layer 224p.

The insulation pattern 220 may be disposed between the storage node contacts 210, and may include a first insulation pattern layer 222 and a second insulation pattern layer 224.

The damaged-portion insulation pattern 220a may include a first damaged-portion insulation pattern layer 222a that is in direct contact with the damaged active region 160a, and a second damaged-portion insulation pattern layer 224a disposed over the first damaged-portion insulation pattern layer 222a.

As is apparent from the above description, the semiconductor device according to the embodiments of the present disclosure may enable the insulation pattern disposed between storage node contacts to include a plurality of insulation pattern layers, so that contact between the active region and the silicon nitride layer due to damage caused in the manufacturing process can be prevented.

The embodiments of the present disclosure may provide a variety of advantageous effects capable of being directly or indirectly recognized by one of ordinary skill in the art.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed. Furthermore, the embodiments may be combined to form additional embodiments.

Although the embodiments of the present disclosure are described with a number of illustrative embodiments, it should be understood that many more modifications and enhancements of the disclosed embodiments and other embodiments may be devised based on what is described and/or illustrated herein. Furthermore, the embodiments may be combined to form additional embodiments.

What is claimed is:

1. A semiconductor device comprising:
an active region, one side of which is in contact with a bitline;
a storage node contact disposed to contact the other side of the active region; and
an insulation pattern disposed between the storage node contact and another storage node contact adjacent to the storage node contact,
wherein the insulation pattern includes a first insulation pattern layer including silicon oxide and a second insulation pattern layer including silicon nitride.

2. The semiconductor device according to claim 1, further comprising:
a wordline extending along a sidewall of the active region; and
a back gate extending parallel to the wordline.

3. The semiconductor device according to claim 2, wherein
the bitline extends in a first direction;
the wordline extends in a second direction; and
the active region extends in a third direction orthogonal to the first and second directions.

4. The semiconductor device according to claim 1, wherein
the active region is in contact with the first insulation pattern layer.

5. The semiconductor device according to claim 1, wherein
the active region includes silicon.

6. The semiconductor device according to claim 1, wherein
the storage node contact includes polysilicon.

7. The semiconductor device according to claim 1, wherein
the first insulation pattern layer is formed through an oxidation process.

8. The semiconductor device according to claim 1, wherein
the first insulation pattern layer is formed through a deposition process.

9. The semiconductor device according to claim 1, wherein
the first insulation pattern layer is formed at a temperature of 900° C or less.

10. A method for manufacturing a semiconductor device, the method comprising:
forming a pre-storage node contact layer over an active region;
etching at least a portion of the pre-storage node contact layer;
forming a first pre-insulation pattern layer over a region where the pre-storage node contact layer is etched;
forming a second pre-insulation pattern layer over the first pre-insulation pattern layer; and
forming an insulation pattern by etching at least a portion of each of the first pre-insulation pattern layer and the second pre-insulation pattern layer.

11. The method according to claim 10, wherein
the active region includes silicon.

12. The method according to claim 10, wherein
the pre-storage node contact layer includes polysilicon.

13. The method according to claim 10, wherein
the first pre-insulation pattern layer is formed through an oxidation process.

14. The method according to claim 10, wherein
the first pre-insulation pattern layer is formed through a deposition process.

15. The method according to claim 10, wherein
the first pre-insulation pattern layer is formed at a temperature of 900° C or less.

16. A method for manufacturing a semiconductor device, the method comprising:
forming a pre-storage node contact layer over first and second active regions;
forming a first storage node contact covering the first active region and a second storage node contact covering a portion of the second active region by etching at least a portion of the pre-storage node contact layer; and
forming a first pre-insulation pattern layer covering the first and second storage node contacts,
wherein the first pre-insulation pattern layer contacts the second active region,
wherein the first pre-insulation pattern layer includes silicon oxide.

17. The method according to claim 16, further comprising:
forming a second pre-insulation pattern layer covering at least a portion of the first pre-insulation pattern layer, the second pre-insulation pattern including silicon nitride.

18. The method according to claim 17, further comprising:
forming a first insulation pattern and a second insulation pattern by etching at least a portion of each of the first pre-insulation pattern layer and the second pre-insulation pattern layer,
wherein the second insulation pattern contacts the second active region,
wherein the first insulation pattern is spaced apart from the first and second active regions.

19. The method according to claim 17, wherein
forming the first pre-insulation pattern layer includes processing the oxidation process, and
forming the second pre-insulation pattern layer includes processing the deposition process.

20. The method according to claim 17, wherein
the second active region is spaced apart from the second pre-insulation pattern layer by the first pre-insulation pattern layer.
